(19) United States
(12) Patent Application Publication
(10) Pub. No.: US 2021/0336175 A1
(43) Pub. Date: Oct. 28, 2021

(54) PEROVSKITE-TYPE ELECTROLUMINESCEN DEVICE AND METHOD FOR FABRICATING SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Pei Jiang, Shenzhen (CN); Chiayu Lee, Shenzhen (CN); Chunche Hsu, Shenzhen (CN); Shujhih Chen, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,599

(22) PCT Filed: Aug. 20, 2019
(86) PCT No.: PCT/CN2019/101465

§ 371 Date: Nov. 27, 2019

(30) Foreign Application Priority Data
Jun. 27, 2019 (CN) 201910566664.7

(51) Int. Cl. H01L 51/50; H01L 51/56

(52) U.S. Cl. CPC H01L 51/5064; H01L 51/56; H01L 51/5032

(57) ABSTRACT

The present disclosure provides a perovskite-type electroluminescent device and a method for fabricating the same. The perovskite-type electroluminescent device comprises a hole transport layer and an emissive layer disposed on the hole transport layer, wherein the hole transport layer comprises an upper hole transport layer and a lower hole transport layer. The lower hole transport layer is a porous structural layer. The upper hole transport layer adopts a material used in conventional hole transport layers. The hole transport layer composed of the upper hole transport layer and the porous structural layer has a high specific surface area that can effectively increase an interface contact area between the hole transport layer and the emissive layer. Therefore, an injection transport rate of holes is increased. This contributes to balance of electron and hole injection transport, thereby increasing external quantum conversion efficiency of the perovskite-type electroluminescent device.

### FIELD OF INVENTION

The present disclosure relates to a field of display panel technology, and particularly to a perovskite-type electroluminescent device and a method for fabricating the same.

### BACKGROUND

Perovskite materials (ABX₃) have characteristics of excellent photoelectric performance, adjustable band gap, low cost, etc., and can be prepared by solution blending. A is selected from methylamine (MA⁺), formamidine (FA⁺), cesium (Cs⁺), organic macromolecules, etc. B is selected from lead (Pb²⁺), tin (Sn²⁺), etc. X is halogen such as chloride (Cl⁻), bromine (Br⁻), iodine (I⁻). At present, in a field of solar cell, photoelectric conversion efficiencies of the perovskite materials have reached 23.7%, surpassing that of traditional silicon-based solar cells. Stability problems of the perovskite materials are being gradually solved. Therefore, the perovskite materials have great commercial prospects.

Subsequently, the perovskite materials are also applied in a field of display. After just four years of development efforts, perovskite light emitting diodes (PeLEDs) emitting red (R) and green (G) light have external quantum conversion efficiency (EQE) of more than 20%, and great potentials for achieving high color purity, wide color gamut, and low cost.

Device structures and working principles of the PeLEDs are similar to those of organic light-emitting devices (OLEDs). Electrons and holes are transported into a perovskite light-emitting layer (EML) through an electron transport layer (ETL) and a hole transport layer (HTL), respectively, to emit light by radiative recombination. At present, research direction of PeLEDs is focused on continuously improving EQE of PeLEDs emitting light of three primary colors R, G, and blue (B). Quality and coverage of a perovskite film of the EML, degree of balance of electron and hole injection transport, and light extraction rate play decisive roles in the EQE of the PeLEDs. Matching among energy levels and mobilities of the ETL, the EML, and the HTL directly determines the degree of the balance of the electron and hole injection transport. In general, an injection transport rate of the ETL will be better than that of the HTL, resulting in electron and hole injection transport imbalance. Therefore, improving injection transport balance between the ETL and the HTL helps to improve the EQE of the PeLEDs. Currently, a commonly used material of the ETL is TPBi, and a commonly used material of the HTL is PEDOT:PSS (Al 4083).

Therefore, it is necessary to develop a new perovskite-type electroluminescent device to overcome the drawbacks of the prior art.

### SUMMARY OF DISCLOSURE

The purpose of the present disclosure is to provide a perovskite-type electroluminescent device in order to solve the problem of electron and hole injection transport imbalance in the prior art.

To achieve the aforementioned purpose, the present disclosure provides a perovskite-type electroluminescent device comprising a hole transport layer and an emissive layer disposed on the hole transport layer, wherein the hole transport layer comprises an upper hole transport layer and a lower hole transport layer, and wherein the lower hole transport layer is a porous structural layer.

The upper hole transport layer adopts a material used in conventional hole transport layers. The hole transport layer composed of the upper hole transport layer and the porous structural layer has a high specific surface area that can effectively increase an interface contact area between the hole transport layer and the emissive layer. Therefore, an injection transport rate of holes is increased. This contributes to balance of electron and hole injection transport, thereby increasing external quantum conversion efficiency of the perovskite-type electroluminescent device.

In an embodiment, the perovskite-type electroluminescent device further comprises an anode layer disposed under the lower hole transport layer, an electron transport layer disposed on the emissive layer, and a cathode layer disposed on the electron transport layer.

In an embodiment, the lower hole transport layer, the porous structural layer, is made of an organic polymer or an inorganic material.

In an embodiment, the inorganic material is one of molybdenum oxide, aluminum oxide or nickel oxide.

In an embodiment, the upper hole transport layer is made of polystyrene sulfonic acid or vanadium oxide.

In an embodiment, the emissive layer is composed of a luminescent material having a perovskite structure.

In an embodiment, the anode layer comprises an electrode having conductivity to transport holes to the hole transport layer, and the cathode layer comprises an electrode having conductivity to transport electrons to the electron transport layer.

The present disclosure further provides a method for fabricating a perovskite-type electroluminescent device comprising:

Step S1: forming an anode layer;

Step S2: forming a lower hole transport layer which is a porous structural layer on the anode layer;

Step S3: forming an upper hole transport layer on the lower hole transport layer;

Step S4: sequentially forming an emissive layer, an electron transport layer, and a cathode layer on the lower hole transport layer.

In an embodiment, in the step S2, the forming the lower hole transport layer is performed by spin coating, etching or printing.

In an embodiment, in the step S3, the forming the upper hole transport layer is performed by spin coating, evaporation or sputtering.

In an embodiment, in the step S3, the lower hole transport layer is annealed first, and then the upper hole transport layer is formed.

The present disclosure provides a perovskite-type electroluminescent device, wherein a composite hole transport layer composed of a porous structural layer and a traditional hole transport layer has a high specific surface area that can effectively increase an interface contact area between the composite hole transport layer and a perovskite emissive layer. Therefore, an injection transport rate of holes is increased. This contributes to balance of electron and hole injection transport, thereby increasing external quantum conversion efficiency of the perovskite-type electroluminescent device.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is across-sectional schematic diagram of a perovskite-type electroluminescent device provided by an embodiment of the present disclosure.

FIG. 2 is a process flow diagram of a method for fabricating a perovskite-type electroluminescent device provided by another embodiment of the present disclosure.

### DETAILED DESCRIPTION

The technical solutions in the embodiments of the present disclosure will be clearly and completely described below in conjunction with the accompanying drawings in the embodiments of the present disclosure. It is apparent that the described embodiments are merely a part of the embodiments of the present disclosure, and not all embodiments. All other embodiments obtained by those skilled in the art based on the embodiments of the present disclosure without creative labor are within the claimed scope of the present disclosure.

The specific structural and functional details disclosed herein are merely representative and are for the purpose of describing exemplary embodiments of the present disclosure. The present disclosure may be embodied in many alternative ways and should not be construed as being limited only to the embodiments described herein.

In the description of the present disclosure, it needs to be understood that orientation or positional relationship indicated by terms “center”, “lateral”, “above”, “below”, “left”, “right”, “vertical”, “horizontal”, “top”, “bottom”, “inside”, “outside”, “side”, etc. is based on orientation or positional relationship shown in the accompanying drawings, and is merely for convenience of describing the present disclosure and simplification of the description. The terms are not intended to indicate or imply that a device or a component must have a particular orientation, or be constructed and operated in a particular orientation. Therefore, the terms are not to be construed as limiting the present disclosure thereto.

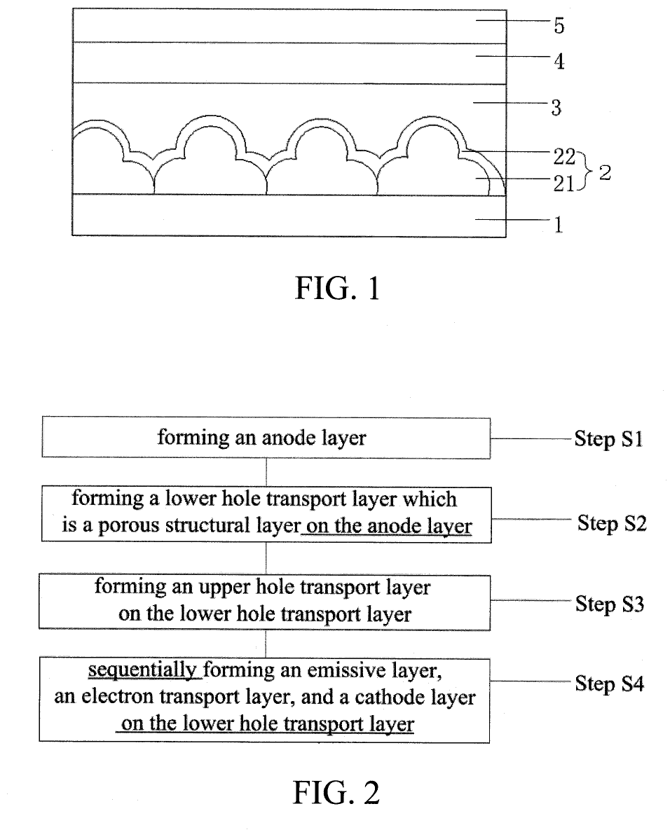

An embodiment of the present disclosure provides a perovskite-type electroluminescent device. Please refer to FIG. 1, which is a cross-sectional schematic diagram of the perovskite-type electroluminescent device provided by the embodiment of the present disclosure. The perovskite-type electroluminescent device comprises an anode layer 1, a hole transport layer 2, an emissive layer 3, an electron transport layer 4, and a cathode layer 5 which are disposed in this order. The hole transport layer 2 is disposed on the anode layer 1, the emissive layer 3 is disposed on the hole transport layer 2, the electron transport layer 4 is disposed on the emissive layer 3, and the cathode layer 5 is disposed on the electron transport layer 4.

In a specific implementation, the anode layer 5 can be specifically made of indium tin oxide (ITO), indium zinc oxide (IZO) or indium gallium zinc oxide (IGZO), but is not limited thereto.

The emissive layer 3 is composed of a luminescent material having a perovskite structure. The perovskite material is an organic hybrid ABX3 having a cubic crystal structure. A is an organic amine group. B is a fourth main group metal or a transition metal. X is a halogen or a combination of halogens.

The anode layer 1 comprises an electrode having conductivity to transport holes to the hole transport layer 2, and the cathode layer 5 comprises an electrode having conductivity to transport electrons to the electron transport layer 4.

The hole transport layer 2 comprises a lower hole transport layer 21 and an upper hole transport layer 22 deposited on the lower hole transport layer 21. The lower hole transport layer 21 is a porous structural layer. The upper hole transport layer 22 adopts a material used in conventional hole transport layers. The hole transport layer 2 composed of the upper hole transport layer 22 and the lower hole transport layer 21 has a high specific surface area that can effectively increase an interface contact area between the hole transport layer 2 and the emissive layer 3. Therefore, an injection transport rate of holes is increased. This contributes to balance of electron and hole injection transport, thereby increasing external quantum conversion efficiency of the perovskite-type electroluminescent device.

In this embodiment, the porous structural layer is made of an organic polymer or an inorganic material, wherein the inorganic material may be molybdenum oxide, aluminum oxide or nickel oxide, but is not limited thereto and can be determined as needed.

In this embodiment, the upper hole transport layer 22 may be made of polystyrene sulfonic acid or vanadium oxide.

Another embodiment of the present disclosure provides a method for fabricating the aforementioned perovskite-type electroluminescent device. Please refer to FIG. 2, which is a process flow diagram of a method for fabricating a perovskite-type electroluminescent device provided by the embodiment of the present disclosure. The method comprises:

Step S1: forming an anode layer;

Step S2: forming a lower hole transport layer which is a porous structural layer on the anode layer by spin coating, etching or printing;

Step S3: forming an upper hole transport layer on the lower hole transport layer by spin coating, evaporation or sputtering, wherein the lower hole transport layer is annealed first, and then the upper hole transport layer is formed;

Step S4: sequentially forming an emissive layer, an electron transport layer, and a cathode layer on the lower hole transport layer.

The present disclosure provides a perovskite-type electroluminescent device, wherein a composite hole transport layer composed of a porous structural layer and a traditional hole transport layer has a high specific surface area that can effectively increase an interface contact area between the composite hole transport layer and a perovskite emissive layer. Therefore, an injection transport rate of holes is increased. This contributes to balance of electron and hole injection transport, thereby increasing external quantum conversion efficiency of the perovskite-type electroluminescent device.

The above description is only preferred embodiments of the present disclosure. it should be noted that those skilled in the art can make various modifications to the above embodiments without departing from the technical idea of the present disclosure, and the modifications are all within the scope defined by the claims of the present disclosure.

1. A perovskite-type electroluminescent device, comprising a hole transport layer and an emissive layer disposed on the hole transport layer; wherein the hole transport layer comprises an upper hole transport layer and a lower hole transport layer, and wherein the lower hole transport layer is a porous structural layer.

2. The perovskite-type electroluminescent device according to claim 1, further comprising an anode layer disposed under the lower hole transport layer, an electron transport layer disposed on the emissive layer, and a cathode layer disposed on the electron transport layer.

3. The perovskite-type electroluminescent device according to claim 1, wherein the lower hole transport layer, the porous structural layer, is made of an organic polymer or an inorganic material.

4. The perovskite-type electroluminescent device according to claim 3, wherein the inorganic material is one of molybdenum oxide, aluminum oxide or nickel oxide.

5. The perovskite-type electroluminescent device according to claim 1, wherein the upper hole transport layer is made of polystyrene sulfonic acid or vanadium oxide.

6. The perovskite-type electroluminescent device according to claim 2, wherein the anode layer comprises an electrode having conductivity to transport holes to the hole transport layer, and the cathode layer comprises an electrode having conductivity to transport electrons to the electron transport layer.

7. A method for fabricating a perovskite-type electroluminescent device, comprising:
Step S1: forming an anode layer;
Step S2: forming a lower hole transport layer which is a porous structural layer on the anode layer;
Step S3: forming an upper hole transport layer on the lower hole transport layer;
Step S4: sequentially forming an emissive layer, an electron transport layer, and a cathode layer on the lower hole transport layer.

8. The method for fabricating the perovskite-type electroluminescent device according to claim 7, wherein in the step S2, the forming the lower hole transport layer is performed by spin coating, etching or printing.

9. The method for fabricating the perovskite-type electroluminescent device according to claim 7, wherein in the step S3, the forming the upper hole transport layer is performed by spin coating, evaporation or sputtering.

10. The method for fabricating the perovskite-type electroluminescent device according to claim 7, wherein in the step S3, the lower hole transport layer is annealed first, and then the upper hole transport layer is formed.

11. The method for fabricating the perovskite-type electroluminescent device according to claim 7, wherein the lower hole transport layer, the porous structural layer, is made of an organic polymer or an inorganic material.

12. The method for fabricating the perovskite-type electroluminescent device according to claim 11, wherein the inorganic material is one of molybdenum oxide, aluminum oxide or nickel oxide.

13. The method for fabricating the perovskite-type electroluminescent device according to claim 7, wherein the upper hole transport layer is made of polystyrene sulfonic acid or vanadium oxide.
